(19) United States
(12) Patent Application Publication
(10) Pub. No.: US 2024/0310416 A1
(43) Pub. Date: Sep. 19, 2024

(54) COMPARATOR CIRCUIT AND VOLTAGE TEST CIRCUIT

(71) Applicant: ROHM Co., LTD., Kyoto (JP)

(72) Inventor: Tamotsu Ichikawa, Kyoto (JP)

(21) Appl. No.: 18/601,013

(22) Filed: Mar. 11, 2024

(30) Foreign Application Priority Data
Mar. 13, 2023 (JP) 2023-038909

(51) Int. Cl. G01R 19/00

(52) U.S. Cl. CPC G01R 19/0038

(57) ABSTRACT

Disclosed herein is a comparator circuit including an amplifier including an auto zero operational amplifier and amplifying a difference between an input voltage and a predetermined first voltage, and a first voltage comparator comparing an output voltage of the amplifier with a predetermined second voltage.

### CROSS REFERENCE TO RELATED APPLICATIONS

This application claims priority benefit of Japanese Patent Application No. JP 2023-038909 filed in the Japan Patent Office on Mar. 13, 2023. Each of the above-referenced applications is hereby incorporated herein by reference in its entirety.

### BACKGROUND

The present disclosure relates to a comparator circuit.

A voltage comparator is used to compare a certain input voltage with a threshold voltage serving as a reference in an electronic circuit. The voltage comparator is generally formed by use of a differential amplifier.

One of important characteristics of the voltage comparator is an output delay time. FIG. 1 is a waveform chart of assistance in explaining an input-output characteristics of the voltage comparator.

An output signal V_{OUT} of the voltage comparator starts to change with the crossing of a threshold voltage V_{TH} by an input voltage V_{IN} as a trigger. The output signal V_{OUT} changes with a certain finite slope (through rate). A degree by which the input voltage V_{IN} after the crossing is separated from the threshold voltage V_{TH} is referred to as an overdrive voltage V_{OD}. The higher the overdrive voltage V_{OD}, the higher the through rate of the output signal V_{OUT} of the voltage comparator. The smaller the overdrive voltage V_{OD}, the lower the through rate. In FIG. 1, a waveform at a time that the overdrive voltage V_{OD} is large is indicated by a solid line (i), and a waveform at a time that the overdrive voltage V_{OD} is small is indicated by a solid line (ii).

An example of the related art is disclosed in Japanese Patent Laid-open No. 2013-153288.

### BRIEF DESCRIPTION OF THE DRAWINGS

FIG. 1 is a waveform chart of assistance in explaining an input-output characteristics of a voltage comparator;

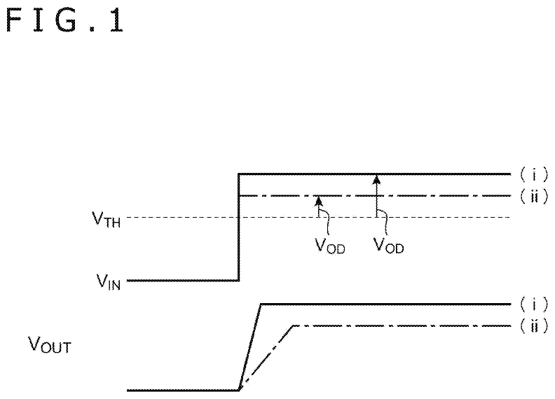

FIG. 2 is a block diagram of a comparator circuit according to an embodiment ;

FIG. 3 is an operation waveform chart of the comparator circuit of FIG. 2;

FIG. 4 is a circuit diagram of a comparator circuit according to one embodiment;

FIG. 5 is a circuit diagram of a comparator circuit according to one embodiment;

FIG. 6 is a circuit diagram of a window comparator according to a comparative technology;

FIG. 7 is a circuit diagram of a concrete example of the comparator circuit of FIG. 5; and

FIG. 8 is a circuit diagram of a voltage test circuit including a comparator circuit.

### DETAILED DESCRIPTION

### Outline of Embodiments

An outline of a few illustrative embodiments of the present disclosure will be described. This outline describes, in a simplified manner, a few concepts of one or a plurality of embodiments as an introduction to the following detailed description for a purpose of basic understanding of the embodiments and does not limit the scope of the disclosure. This outline is neither a comprehensive outline of all conceivable embodiments nor intended to identify important elements of all of the embodiments or demarcate the scope of part or all of examples. For convenience, “one embodiment” may be used to refer to one embodiment (an example or a modification) or a plurality of embodiments (examples or modifications) disclosed in the present specification.

A comparator circuit according to one embodiment includes an amplifier including an auto zero operational amplifier and amplifying a difference between an input voltage and a predetermined first voltage, and a first voltage comparator comparing an output voltage of the amplifier with a predetermined second voltage.

Letting V_{TH} be a threshold voltage of the comparator circuit viewed as a whole, a difference between the input voltage V_{IN} and the threshold voltage V_{TH} is an overdrive voltage V_{OD(TOTAL)} of the comparator circuit as a whole. Even in a case where the overdrive voltage V_{OD(TOTAL)} is small, the difference between the input voltage V_{IN} and the threshold voltage V_{TH} is amplified by a gain g. Thus, an overdrive voltage V_{OD(COMP)} in the first voltage comparator in a rear stage becomes very large. The voltage comparator in the rear stage can consequently operate at a high speed. Hence, the comparator circuit can compare the input voltage V_{TH} close to the threshold voltage V_{IN} at a high speed.

In one embodiment, the comparator circuit may further include a second voltage comparator comparing the output voltage of the amplifier with a predetermined third voltage, and the comparator circuit may operate as a window comparator. It is thereby possible to realize a very narrow window width.

In one embodiment, the first voltage comparator and the second voltage comparator may have an output stage of an open collector or an open drain. Outputs of the first voltage comparator and the second voltage comparator may be pulled up by a common resistance.

In one embodiment, the amplifier may be a subtraction circuit.

A voltage test circuit according to one embodiment may include the above-described comparator circuit capable of operating as a window comparator, and a variable voltage source generating the first voltage having a voltage level corresponding to an expected value of the input voltage.

### Embodiments

The present disclosure will hereinafter be described with reference to the drawings on the basis of preferred embodiments. Identical or equivalent constituent elements, members, and processing illustrated in each drawing are identified by the same reference numerals, and repeated description thereof will be omitted as appropriate. In addition, the embodiments are not restrictive of the disclosure but is illustrative, and all features described in the embodiments and combinations thereof are not necessarily essential to the disclosure.

In the present specification, a “state in which a member A is connected to a member B” includes a case where the member A and the member B are physically directly connected to each other and a case where the member A and the member B are indirectly connected to each other via another member that does not affect an electrically connected state.

Similarly, a “state in which a member C is provided between the member A and the member B” includes not only a case where the member A and the member C or the member B and the member C are directly connected to each other but also a case where the member A and the member C or the member B and the member C are indirectly connected to each other via another member that does not affect an electrically connected state.

In addition, a “signal A (voltage or current) is determined according to a signal B (voltage or current) ” means that the signal A has correlation to the signal B, and specifically means: (i) a case where the signal A is the signal B; (ii) a case where the signal A is in proportion to the signal B; (iii) a case where the signal A is obtained by level-shifting the signal B; (iv) a case where the signal A is obtained by amplifying the signal B; (v) a case where the signal A is obtained by inverting the signal B; (vi) any combination thereof; or the like. It is understood by those skilled in the art that the scope of “according” is determined according to kinds and uses of the signals A and B.

Axes of ordinates and axes of abscissas in waveform charts and timing charts referred to in the present specification are enlarged or reduced in scale as appropriate in order to facilitate understanding, and each waveform illustrated therein is simplified or exaggerated or emphasized in order to facilitate understanding.

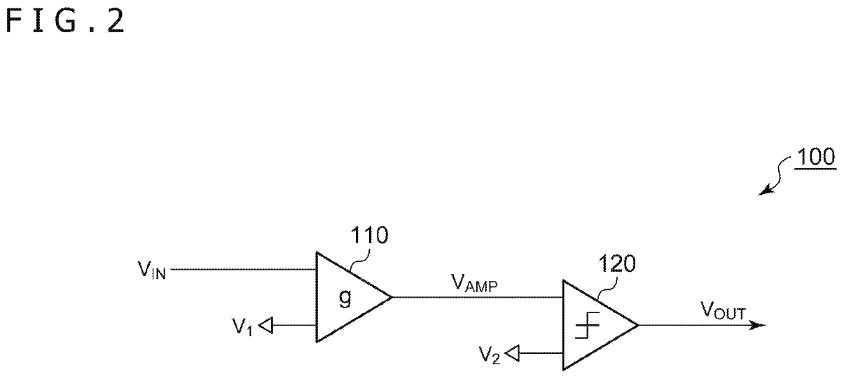

FIG. 2 is a block diagram of a comparator circuit 100 according to an embodiment. The comparator circuit 100 includes an amplifier 110 in a front stage and a first voltage comparator 120 in a rear stage.

The comparator circuit 100 compares the input voltage V_{IN} with the threshold voltage V_{TH}, and generates an output signal V_{OUT} that indicates a result of the comparison.

The amplifier 110 amplifies a difference between the input voltage V_{IN} and a first voltage V₁. The amplifier 110 is formed by use of an auto zero operational amplifier (referred to also as an auto zero amplifier or a zero drift amplifier). The amplifier 110 is very little affected by an offset voltage of the operational amplifier. The amplifier 110 amplifies the difference between the input signal V_{IN} and the first voltage V₁ in an offset-free manner. An output voltage of the amplifier 110 after the amplification will be referred to as V_{AMP}.

The first voltage comparator 120 compares the output voltage V_{AMP} of the amplifier 110 with a second voltage V₂, and generates an output signal V_{OUT} indicating magnitude relation therebetween. The first voltage comparator 120 can be constituted by an ordinary differential amplifier.

The configuration of the comparator circuit 100 has been described above. An operation thereof will next be described.

The amplifier 110 in the front stage is constituted by use of an auto zero operational amplifier, and is therefore able to amplify the difference between the input voltage V_{IN} and the first voltage V₁ with a very small offset voltage. When generalized, the output voltage V_{AMP} of the amplifier is expressed by

$${V}_{AMP} = g \times ( {V}_{IN} - {V}_{1} ) + {V}_{COM} \qquad ( 1 )$$

in which g is a gain of the amplifier 110 and V_{COM} is a reference voltage of the amplifier 110. The gain g can be set to be, for example, 10 times or more, preferably 100 times or more, and may be set to be 1000 times or more.

The first voltage comparator 120 in the rear stage compares the output voltage V_{AMP} of the amplifier 110 and the second voltage V₂ with each other. In the comparator circuit 100, V_{AMP}=V₂ holds when V_{IN}=V_{TH}. Hence, Equation (2) is obtained.

$${V}_{2} = g \times ( {V}_{TH} - {V}_{1} ) + {V}_{COM} \qquad ( 2 )$$

Hence, the threshold voltage V_{TH} is expressed by Equation (3).

$${V}_{TH} = ( {V}_{2} - {V}_{COM} ) / g + {V}_{1} \qquad ( 3 )$$

An overdrive voltage as a minimum required to make the voltage comparator 120 in the rear stage operate at a speed satisfying design specifications (this overdrive voltage will be referred to as a minimum overdrive voltage in the present specification) will be referred to as V_{OD(MIN)}. An amplified voltage V_{AMP(MIN)} that gives the minimum overdrive voltage V_{OD(MIN)} is

$${V}_{AMP ( MIN )} = {V}_{2} + {V}_{OD ( MIN )} \qquad ( 4 )$$

An input voltage V_{IN(MIN)} that gives the amplified voltage V_{AMP(MIN)} of Equation (4) can be calculated from Equation (1).

$${V}_{IN ( MIN )} = ( {V}_{AMP ( MIN )} - {V}_{COM} ) / g + {V}_{1} \qquad ( 5 )$$

Equation (6) is obtained when Equation (4) is substituted into Equation (5).

$${V}_{IN ( MIN )} = ( {V}_{2} + {V}_{OD ( MIN )} - {V}_{COM} ) / g + {V}_{1} \qquad ( 6 )$$

A difference between the input voltage V_{IN(MIN)} Of Equation (6) and the threshold voltage V_{TH} of Equation (3) is a minimum overdrive voltage V_{OD_TOTAL(MIN)} of the comparator circuit 100 as a whole.

$$\begin{matrix}{V}_{OD \_ TOTAL ( MIN )} = {V}_{IN ( MIN )} - {V}_{TH} \\ = ( {V}_{2} + {V}_{OD ( MIN )} - {V}_{COM} ) / g + {V}_{1} - \\ \{ ( {V}_{2} - {V}_{COM} ) / g + {V}_{1} \} \\ = {V}_{OD ( MIN )} / g\end{matrix} \qquad ( 7 )$$

That is, the minimum overdrive voltage V_{OD_TOTAL(MIN)} of the comparator circuit 100 as a whole is a value obtained by dividing the minimum overdrive voltage V_{OD(MIN)} of the first voltage comparator 120 alone by the gain g. Hence, even when a comparator whose minimum overdrive voltage is on the order of mV is employed as the first voltage comparator 120, for example, the overdrive voltage V_{OD_TOTAL(MIN)} of the input voltage VIN, that is, an effective overdrive voltage of the comparator circuit 100 as a whole is on the order of sub-mV, and thus, a high-speed voltage comparison is enabled with a very small overdrive voltage.

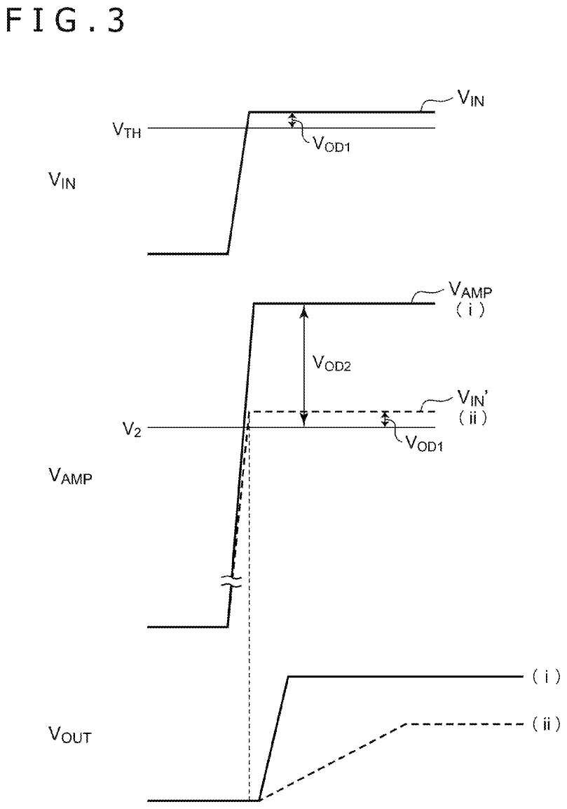

FIG. 3 is an operation waveform chart of the comparator circuit 100 in FIG. 2. An upper part of FIG. 3 illustrates the input signal V_{IN} and the threshold voltage V_{TH}. A middle part of FIG. 3 illustrates the signal V_{AMP} obtained after being subjected to amplification and the second voltage V₂. A lower part of FIG. 3 illustrates the output signal V_{OUT}.

An overdrive voltage V_{OD2} (=V_{AMP}−V₂) in the first voltage comparator 120 has a magnitude g times an overdrive voltage V_{OD1} (=V_{IN}−V_{TH}) of the input voltage V_{IN} with respect to the threshold voltage V_{TH}.

Advantages of the comparator circuit 100 are clarified by comparison with a comparative technology. In the comparative technology, the amplifier 110 in the front stage is omitted, and an input signal V_{IN}′ is supplied directly to the first voltage comparator 120 in the rear stage. Operation waveforms of the comparative technology are indicated by broken lines (ii) in FIG. 3. In the comparative technology, the overdrive voltage V_{OD1} in the first voltage comparator 120 is small, and therefore, the output signal V_{OUT} makes a slow transition as indicated by a broken line (ii).

In the present embodiment, on the other hand, the overdrive voltage V_{OD2} in the first voltage comparator 120 is large, and therefore, the output signal V_{OUT} makes a quick transition. Hence, the comparator circuit 100 can operate at a high speed with a very small overdrive voltage V_{OD1}.

The present disclosure covers various devices and methods understood as the block diagram or the circuit diagram of FIG. 2 or derived from the above description, and is not limited to a specific configuration. In the following, more specific configuration examples and embodiments will be described not to narrow the scope of the present disclosure but to facilitate the understanding of the essence and operation of the present disclosure and clarify the essence and the operation of the present disclosure.

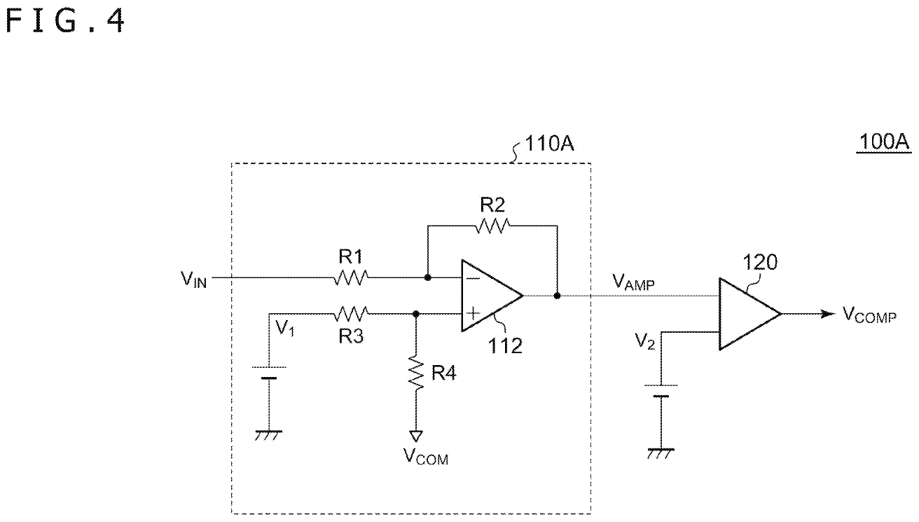

FIG. 4 is a circuit diagram of a comparator circuit 100A according to one embodiment. An amplifier 110A is a subtraction circuit. The amplifier 110A includes an operational amplifier 112, a first resistance R1, a second resistance R2, a third resistance R3, and a fourth resistance R4. The operational amplifier 112 is an auto zero operational amplifier. When R1=R3 and R2=R4 hold, the output voltage V_{AMP} of the amplifier 110A is expressed by Equation (8).

$${V}_{AMP} = ( {V}_{1} - {V}_{IN} ) \times R 2 / R 1 + {V}_{COM} \qquad ( 8 )$$

When Equation (1) and Equation (8) are compared with each other, g=−R2/R1. V_{COM} may be 0 V or may be any nonzero voltage.

Supposing that V₂=V_{COM}, the threshold voltage V_{TH} of the comparator circuit 100A can be calculated by substituting V₂=V_{COM} into Equation (3) and is expressed by Equation (9).

$${V}_{TH} = {V}_{1} \qquad ( 9 )$$

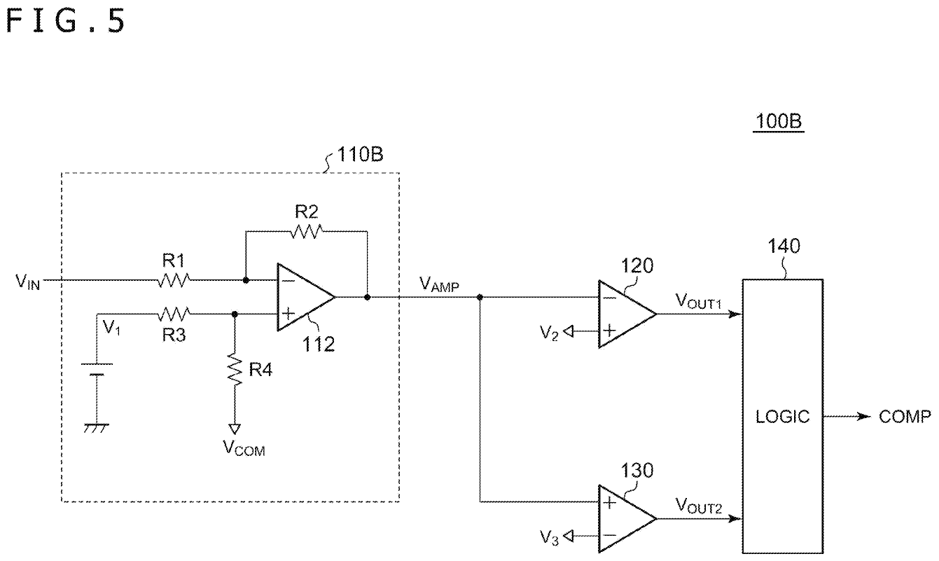

FIG. 5 is a circuit diagram of a comparator circuit 100B according to one embodiment. The comparator circuit 100B is a window comparator. The comparator circuit 100B determines whether or not the input voltage V_{IN} is included in a voltage window having V₁ as a lower limit and having V_{J} as an upper limit.

The comparator circuit 100B includes an amplifier 110B, a first voltage comparator 120, and a second voltage comparator 130. A configuration of the amplifier 110B is similar to that of the amplifier 110A in FIG. 4, and is constituted by a subtraction circuit.

The first voltage comparator 120 compares the amplified voltage V_{AMP} with the second voltage V₂ and generates a first output signal V_{OUT1} indicating a result of the comparison. The second voltage comparator 130 compares the amplified voltage V_{AMP} with a third voltage V₃ and generates a second output signal V_{OUT2} indicating a result of the comparison.

The first voltage comparator 120 compares the input voltage V_{IN} with an upper side threshold voltage V_{H} expressed by Equation (10).

$${V}_{H} = ( {V}_{2} - {V}_{COM} ) / g + {V}_{1} \qquad ( 10 )$$

The second voltage comparator 130 compares the input voltage V_{IN} with a lower side threshold voltage V_{L} expressed by Equation (11).

$${V}_{L} = ( {V}_{3} - {V}_{COM} ) / g + {V}_{1} \qquad ( 11 )$$

The second voltage V₂ and the third voltage V₃ can be, for example, defined so as to satisfy the following relations.

$$\begin{matrix}{V}_{2} = {V}_{COM} + ΔV \\ {V}_{3} = {V}_{COM} - ΔV\end{matrix}$$

In this case,

$$\begin{matrix}{V}_{H} = {V}_{1} + ΔV / g \\ {V}_{L} = {V}_{1} - ΔV / g\end{matrix}$$

The comparator circuit 100B may further include a logic circuit 140. The logic circuit 140 receives two output signals V_{OUT1} and V_{OUT2}. The logic circuit 140 outputs a comparison signal COMP that is at a first level as one of a high and a low when the input signal V_{IN} is included in the window, and a comparison signal COMP that is at a second level as the other of the high and the low when the input signal V_{IN} is not included in the window.

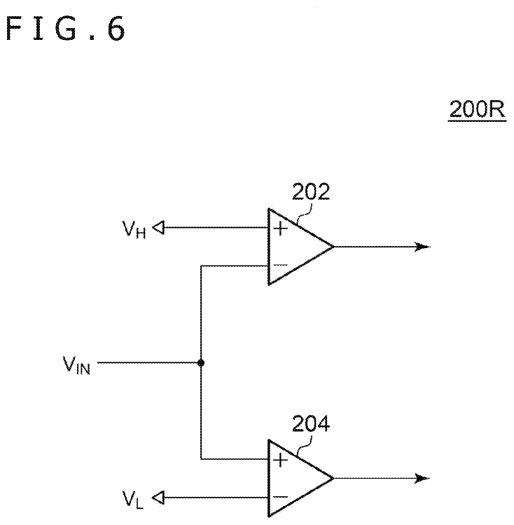

Advantages of the comparator circuit 100B are clarified by comparison with a comparative technology. FIG. 6 is a circuit diagram of a window comparator 200R according to the comparative technology. The window comparator 200R includes voltage comparators 202 and 204. Suppose that the minimum overdrive voltage of the voltage comparators 202 and 204 is V_{OD(MIN)}. In this case, a window width ΔV=V_{H}−V_{L} is limited by the minimum overdrive voltage V_{OD(MIN)}.

ΔV≥V_{OD(MIN)}

This is because, supposing that ΔV<V_{OD(MIN)}, when the input voltage V_{IN} makes a transition from outside the window to within the window, a difference between V_{IN} and the threshold voltage V_{H} (or V_{L}) becomes smaller than the minimum overdrive voltage V_{OD(MIN)}.

Hence, in the comparative technology, in a case where the minimum overdrive voltage V_{OD(MIN)} is on the order of mV, the window width of the comparator circuit 100B is on the order of mV.

On the other hand, in the embodiment of FIG. 5, even when the overdrive voltage of V_{IN} with respect to V_{H} or the overdrive voltage of V_{IN} with respect to V₁ is on the order of sub-mV (on the order of μV), overdrive voltages V_{AMP}−V₂ and V_{AMP}−V₃ in the first voltage comparator 120 and the second voltage comparator 130 in the rear stage are larger than the minimum overdrive voltage V_{OD(MIN)}. Hence, a window comparator having a sub-mV window width can be formed.

Incidentally, in the comparator circuit 100B of FIG. 5, the second voltage V₂ and the third voltage V₃ may be defined so as to satisfy the following relations.

$$\begin{matrix}{V}_{2} = {V}_{COM} \\ {V}_{3} = {V}_{COM} - ΔV\end{matrix}$$

In this case,

$$\begin{matrix}{V}_{H} = {V}_{1} \\ {V}_{L} = - ΔV / g + {V}_{1}\end{matrix}$$

Alternatively, the second voltage V₂ and the third voltage V₃ may be defined so as to satisfy the following relations.

$$\begin{matrix}{V}_{2} = {V}_{COM} + ΔV \\ {V}_{3} = {V}_{COM}\end{matrix}$$

In this case,

$$\begin{matrix}{V}_{H} = ΔV / g + {V}_{1} \\ {V}_{L} = {V}_{1}\end{matrix}$$

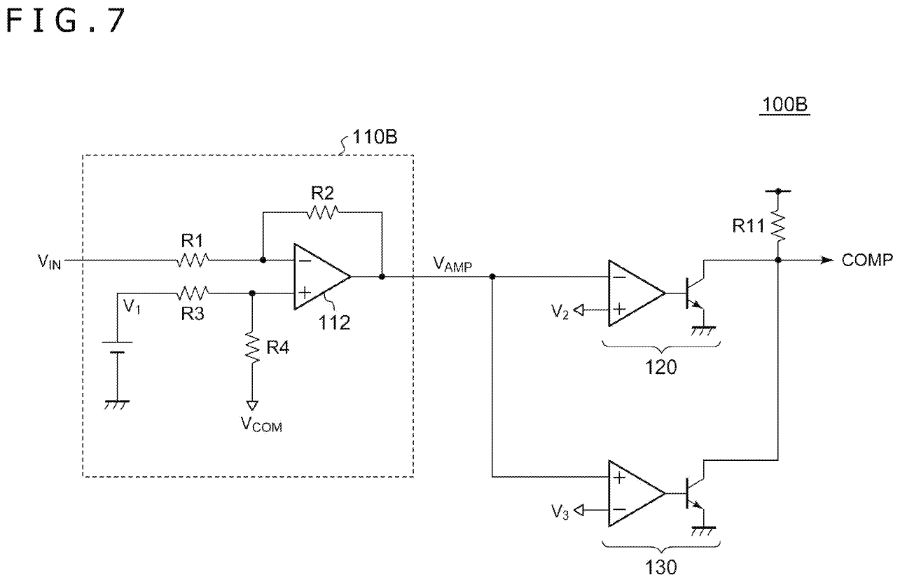

FIG. 7 is a circuit diagram of a specific example of the comparator circuit 100B of FIG. 5. The first voltage comparator 120 and the second voltage comparator 130 have an output form of an open collector (open drain). The logic circuit 140 includes a resistance R11 that pulls up the respective outputs of the first voltage comparator 120 and the second voltage comparator 130. The resistance R11 and output transistors Q11 and Q12 of the first voltage comparator 120 and the second voltage comparator 130 constitute an OR circuit.

An application of the comparator circuit 100 will next be described.

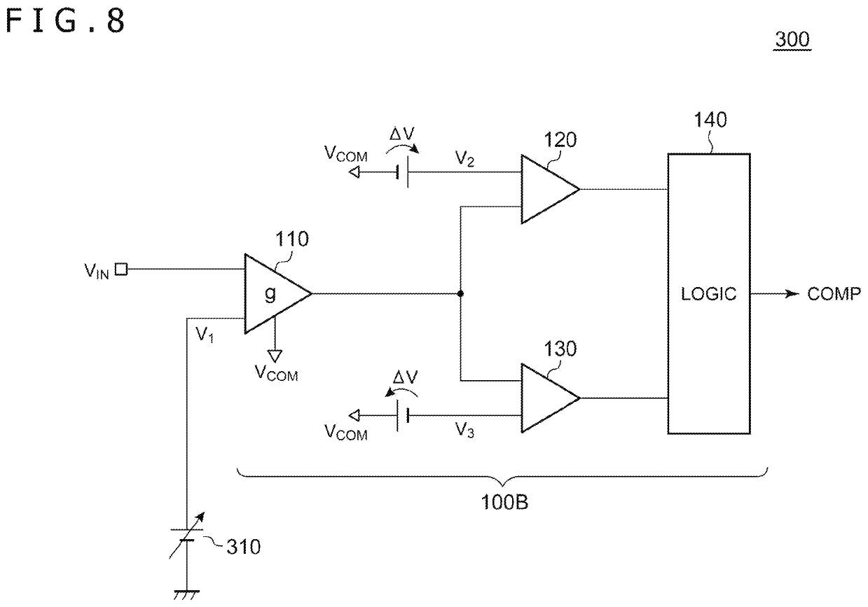

FIG. 8 is a circuit diagram of a voltage test circuit 300 including the comparator circuit 100B. The voltage test circuit 300 determines whether or not the input voltage VIN is included in an expected voltage level of the input voltage. The voltage test circuit 300 includes the above-described comparator circuit 100B and a variable voltage source 310. The variable voltage source 310 generates the first voltage V₁ according to the expected value level of the input voltage V_{IN}. According to this configuration, the voltage test circuit 300 can determine whether the input voltage V_{IN} is included in a voltage range based on the expected value level. The absolute value of the input voltage V_{IN} can be ensured by performing a test with use of the voltage test circuit 300.

For example, the voltage test circuit 300 can test a D/A converter. Specifically, while an input code of the D/A converter is swept, the output voltage V₁ of the variable voltage source 310 is swept so as to follow the sweeping of the input code. It is thereby possible to test the D/A converter at a high speed.

The applications of the comparator circuit 100 is not particularly limited, and the comparator circuit 100 can widely be used for voltage comparison applications.

The present disclosure has been described with particular words on the basis of embodiments. However, the embodiments merely represent principles and applications of the present disclosure, and many modifications and changes in arrangement are recognized in the embodiments without departing from the concepts of the present disclosure as defined in claims.

### SUPPLEMENTARY NOTES

The technology disclosed in the present specification are grasped as follows in one example.

### (Item 1)

A comparator circuit including:
an amplifier including an auto zero operational amplifier and amplifying a difference between an input voltage and a predetermined first voltage; and
a first voltage comparator comparing an output voltage of the amplifier with a predetermined second voltage.

### (Item 2)

The comparator circuit according to Item 1, further including:
a second voltage comparator comparing the output voltage of the amplifier with a predetermined third voltage,
in which the comparator circuit operates as a window comparator.

### (Item 3)

The comparator circuit according to Item 2, in which
the first voltage comparator and the second voltage comparator have an output stage of an open collector or an open drain, and
outputs of the first voltage comparator and the second voltage comparator are pulled up by a common resistance.

### (Item 4)

The comparator circuit according to any one of Items 1 to 3, in which
the amplifier is a subtraction circuit.

### (Item 5)

A voltage test circuit including:
the comparator circuit according to Item 2 or 3; and
a variable voltage source generating the first voltage having a voltage level corresponding to an expected value of the input voltage.

According to a certain example of the present disclosure, a comparator circuit capable of operating with an overdrive voltage on the order of sub-mV is provided.

What is claimed is:

1. A comparator circuit comprising:
an amplifier including an auto zero operational amplifier and amplifying a difference between an input voltage and a predetermined first voltage; and
a first voltage comparator comparing an output voltage of the amplifier with a predetermined second voltage.

2. The comparator circuit according to claim 1, further comprising:
a second voltage comparator comparing the output voltage of the amplifier with a predetermined third voltage,
wherein the comparator circuit operates as a window comparator.

3. The comparator circuit according to claim 2, wherein
the first voltage comparator and the second voltage comparator have an output stage of an open collector or an open drain, and
outputs of the first voltage comparator and the second voltage comparator are pulled up by a common resistance.

4. The comparator circuit according to claim 1, wherein
the amplifier is a subtraction circuit.

5. A voltage test circuit comprising:
the comparator circuit according to claim 2; and
a variable voltage source generating the first voltage having a voltage level corresponding to an expected value of the input voltage.
